(19) United States
(12) Patent Application Publication
(10) Pub. No.: US 2021/0200353 A1
(43) Pub. Date: Jul. 1, 2021

(54) DISPLAY SCREEN AND ELECTRONIC DEVICE THEREOF

(71) Applicant: Wuhan China Star Optoelectronics Semiconductor Display Technology Co., Ltd., Wuhan, Hubei (CN)

(72) Inventors: Minlun LIU, Wuhan, Hubei (CN); Qibing DAI, Wuhan, Hubei (CN); Dan LIN, Wuhan, Hubei (CN)

(73) Assignee: Wuhan China Star Optoelectronics Semiconductor Display Technology Co., Ltd., Wuhan, Hubei (CN)

(21) Appl. No.: 17/057,718

(22) PCT Filed: Jan. 2, 2019
(86) PCT No.: PCT/CN2019/070134

§ 371 Date: Nov. 23, 2020

(30) Foreign Application Priority Data
Dec. 4, 2018 (CN) 201811471495.0

(51) Int. Cl. G06F 3/041; G06F 3/044

(52) U.S. Cl. CPC G06F 3/0412; G06F 3/0443; H01L 27/323; G06F 3/0446; G06F 2203/04112; G06F 3/04164

(57) ABSTRACT

A display screen and an electronic apparatus. The display screen comprises: a touch layer positioned above a display layer and comprising multiple metal grid electrodes and multiple drive lines, wherein the metal grid electrodes correspond to the drive lines; the metal grid electrodes are electrically connected to the corresponding drive lines; and the metal grid electrodes and the drive lines all correspond to the positions of gaps between sub-pixels.

### BACKGROUND

### Field

The present disclosure relates to a technical field of display devices, and more particularly to a display screen and an electronic device thereof.

### Background

Touch screen can be divided into four types of infrared touch screens, capacitive touch screens, resistance touch screens, and surface acoustic wave touch screen, where because the capacitive touch screens have a long lifetime and high light transmittance, and are capable of truly supporting multi-point touch control and the like, and the capacitive touch screens are a current mainstream of touch screen technology.

The capacitive touch screens include types of surface capacitance and projection capacitance, where the type of projection capacitance can be divided into a self-capacitance type and a mutual capacitance type. The mutual capacitance type usually uses indium tin oxide (ITO) for forming a sensing electrode Rx and a scanning electrode Tx on the surface of the display screen. A coupling capacitor is formed on an intersection region of two sets of electrodes intersect and the two sets of electrodes serve as the two poles of the coupling capacitor respectively. When a finger contacts the capacitive touch screen, a coupling action between two electrodes near contact points is affected, such that amount of the coupling capacitance of the coupling capacitor between the two electrodes is changed.

However, a conventional touch screen is directly adhered to a display screen, thereby enlarging the thickness of the display screen. Moreover, because the sensing electrode Rx and the scanning electrode Tx may shield light rays of the display screen, thereby reducing aperture ratio of the display screen and increasing the power consumption.

Therefore, there is a need to provide a display screen and an electronic device to solve the above-mentioned problems of conventional touch screens.

### SUMMARY OF THE DISCLOSURE

The present disclosure aims to provide a display screen and an electronic device, thereby increasing the aperture ratio of the display screen and reducing the power consumption of the display screen.

In order to solve above-mentioned technical problems, the present disclosure provides a display screen comprising:

a display layer comprising a display region, wherein the display region comprises a plurality of sub-pixels arranged at intervals; and

a touch layer disposed above the display layer and comprising a plurality of metal mesh electrodes and a plurality of driving lines, wherein the metal mesh electrodes correspond to the driving line, the metal mesh electrodes are electrically connected with the corresponding driving lines, the metal mesh electrodes and the driving lines correspond to positions of gaps between the sub-pixels respectively, and the metal mesh electrode comprises a plurality of first electrodes arranged in the first direction and a plurality of second electrodes arranged in the second direction;

wherein the metal mesh electrodes and the driving lines are disposed on different metal layers, the metal mesh electrodes are electrically connected with the driving lines correspondingly through a plurality of connecting holes, and two adjacent metal mesh electrodes are arranged at intervals.

In an embodiment of the display screen, positions of the connecting holes correspond to the positions of the gaps between the sub-pixels.

In an embodiment of the display screen, the metal mesh electrodes are disposed on a second metal layer, the driving lines are disposed on a first metal layer, and the second metal layer is disposed on the first metal layer.

In an embodiment of the display screen, lengths of the metal mesh electrodes are equal, and widths of the metal mesh electrodes are equal.

In an embodiment of the display screen, positions of the metal mesh electrodes correspond to a position of the display region.

In an embodiment of the display screen, the first electrodes and the second electrodes are arranged in an intersection manner, and the driving lines are electrically connected with intersection points between the first electrodes and the second electrodes.

In an embodiment of the display screen, the display screen further comprises a plurality of binding ends, and one end of each of the driving lines is connected with a metal mesh electrode, and the other end of each of the driving lines is connected with a binding end.

The present disclosure provides a display screen, comprising:

a display layer comprising a display region, wherein the display region comprises a plurality of sub-pixels arranged at intervals; and

a touch layer disposed above the display layer and comprising a plurality of metal mesh electrodes and a plurality of driving lines, wherein the metal mesh electrodes correspond to the driving line, the metal mesh electrodes are electrically connected with the corresponding driving lines, the metal mesh electrodes and the driving lines correspond to positions of gaps between the sub-pixels respectively, and the metal mesh electrode comprises a plurality of first electrodes arranged in the first direction and a plurality of second electrodes arranged in the second direction.

In an embodiment of the display screen, the metal mesh electrodes and the driving lines are disposed on different metal layers, and the metal mesh electrodes are electrically connected with the driving lines correspondingly through a plurality of connecting holes.

In an embodiment of the display screen, positions of the connecting holes correspond to the positions of the gaps between the sub-pixels.

In an embodiment of the display screen, the metal mesh electrodes are disposed on a second metal layer, the driving lines are disposed on a first metal layer, and the second metal layer is disposed on the first metal layer.

In an embodiment of the display screen, two adjacent metal mesh electrodes are arranged at intervals.

In an embodiment of the display screen, lengths of the metal mesh electrodes are equal, and widths of the metal mesh electrodes are equal.

In an embodiment of the display screen, the positions of the metal mesh electrodes correspond to a position of the display region.

In an embodiment of the display screen, the first electrodes and the second electrodes are arranged in an intersection manner, and the driving lines are electrically connected with intersection points between the first electrodes and the second electrodes.

In an embodiment of the display screen, the display screen further comprises a plurality of binding ends, and one end of each of the driving lines is connected with a metal mesh electrode, and the other end of each of the driving lines is connected with a binding end.

The present disclosure provides an electronic device comprising a display layer as described above.

According to the display screen and the electronic device of the present disclosure, the metal mesh electrodes and the driving lines are arranged in the positions of gaps between the sub-pixels, thereby increasing the aperture ratio of the display screen and reducing the power consumption of the display screen.

### BRIEF DESCRIPTION OF THE DRAWINGS

The following embodiments refer to the accompanying drawings for exemplifying specific implementable embodiments of the present disclosure in a suitable computing environment. It should be noted that the exemplary described embodiments are configured to describe and understand the present disclosure, but the present disclosure is not limited thereto.

FIG. 1 is a schematic structural diagram of a display screen according to an embodiment of the present disclosure.

FIG. 2 is a top view of a display screen according to an embodiment of the present disclosure.

FIG. 3 is a schematically enlarged structural diagram of a single metal mesh electrode of FIG. 2 according to an embodiment of the present disclosure.

FIG. 4 is a schematic structural diagram of a metal mesh electrode according to an embodiment of the present disclosure.

FIG. 5 is a simplified structure diagram of a touch control layer according to an embodiment of the present disclosure.

### DETAILED DESCRIPTION OF THE PREFERRED EMBODIMENTS

The following embodiments refer to the accompanying figures for exemplifying specific implementable embodiments of the present disclosure in a suitable computing environment. It should be noted that the exemplary described embodiments are configured to describe and understand the present disclosure, but the present disclosure is not limited thereto. Directional terms, such as an upper side, a lower side, a front side, a back side, a left side, a right side, an inner side, an outer side, and a lateral side, mentioned in the present disclosure are only for reference. Therefore, the directional terms are used for describing and understanding rather than limiting the present disclosure. In the figures, units having similar structures are used for the same reference numbers.

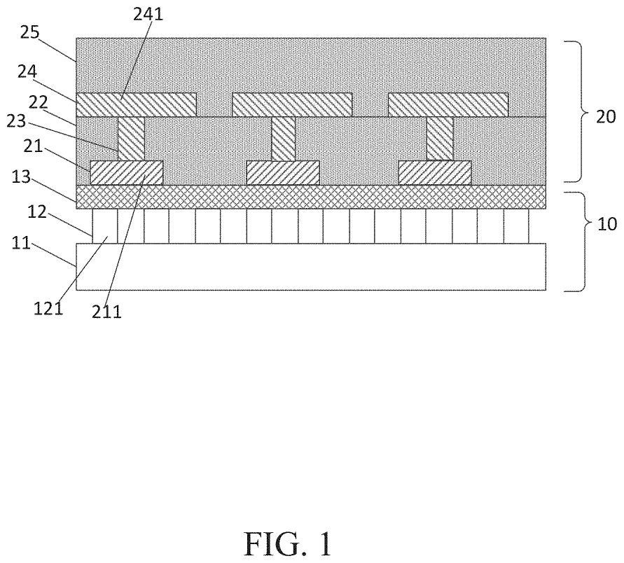

Please refer to FIGS. 1-5. FIG. 1 is a schematic structural diagram of a display screen according to an embodiment of the present disclosure.

As shown in FIG. 1, the display screen of the present disclosure includes a display layer 10 and a touch control layer 20, where the touch layer 20 is disposed above the display layer 10.

In an embodiment, the display screen 10 is an organic light emitting diode display screen. A cross-sectional structure of the display layer 10 includes a substrate 11, an organic light-emitting layer 12, and a thin film packaging layer 13, where the organic light-emitting layer 12 and the thin film packaging layer 13 are formed on the substrate 11 in sequence. The organic light-emitting layer 12 includes a plurality of organic light-emitting units 121. The substrate 11 includes a substrate and a switch array layer. The switch array layer includes a plurality of thin film transistors.

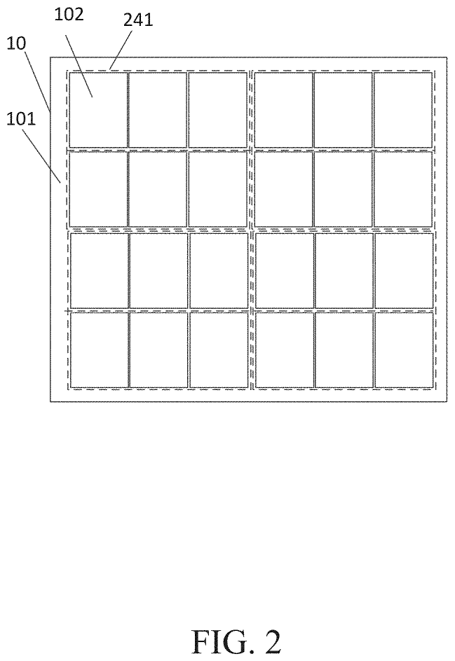

As shown in a top view of FIG. 2, the display layer 10 includes a display region 101, where the display region 101 includes a plurality of sub-pixels 102 arranged at intervals, and the sub-pixels 102 correspond to the positions of the organic light-emitting units 121.

In FIG. 1, a cross-sectional structure of the touch-control layer 20 includes a first metal layer 21 and a first insulating layer 22, a second metal layer 24, and a second insulating layer 25, where a connecting hole 23 is disposed in the first insulating layer 22. For example, the touch control layer is a self-capacitance touch control layer.

As shown in a top view of FIGS. 2-5, the touch layer 20 includes a plurality of metal mesh electrodes 241 (represented by a dotted line frame) and a plurality of driving lines 211, where the positions of the plurality of metal mesh electrodes 241 correspond to the positions of the display region 101. The plurality of metal mesh electrodes 241 are arranged in the whole display region 101, and two adjacent metal mesh electrodes 241 are arranged at intervals.

In order to improve touch sensitivity of a touch screen, in an embodiment, a length of each of the metal mesh electrodes 241 is equal, and a width of each of metal mesh electrodes 241 is equal. For example, a plurality of metal mesh electrodes 241 with equal size is disposed at a position corresponding to the display region 101. For example, there are four metal mesh electrodes 241 with the same area, as shown in FIG. 2.

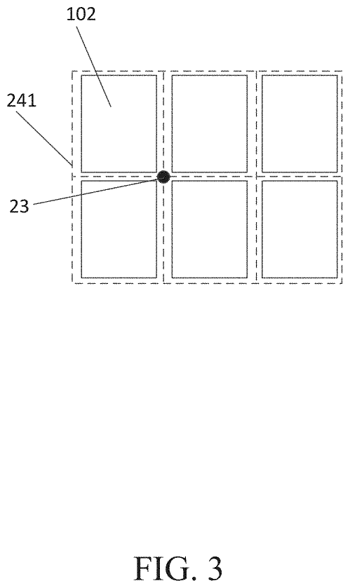

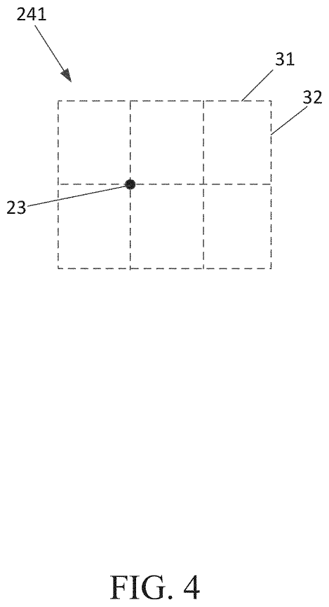

In FIGS. 3 and 4, a metal mesh electrode 241 is taken as an example. Each of the metal mesh electrodes 241 includes a plurality of first electrodes 31 arranged in a first direction and a plurality of second electrodes 32 arranged in the second direction, where the first direction intersects with the second direction. The shape of each of the metal mesh electrodes 241 is in a grid shape. In an embodiment of FIG. 4, the metal mesh electrode 241 includes three first electrodes 31 arranged in a horizontal direction and four second electrodes 32 arranged in a vertical direction, where the first electrodes 31 are parallel to the horizontal line and the second electrodes 32 are parallel to the vertical line. Both the first electrodes 31 and the second electrodes 32 are disposed in a gap between the sub-pixels 102. Because the metal mesh electrodes has the fold-resistant characteristics, the design can be applied to products of flexible folding and curling features.

In order to improve touch sensitivity of a touch screen, combined with an embodiment of FIG. 4, the first electrodes 31 and the second electrodes 32 are arranged in an intersection manner, a plurality of intersection points are arranged between the first electrodes 31 and the second electrodes 32, where driving lines 211 are electrically connected with the intersection points between the first electrodes 31 and the second electrodes 32. In an embodiment, the driving lines 211 are electrically connected with the intersection points between the first electrodes 31 and the second electrodes 32 through a connecting hole 23. In another embodiment, the driving lines 211 can be electrically connected with the first electrodes 31 or the second electrodes 32.

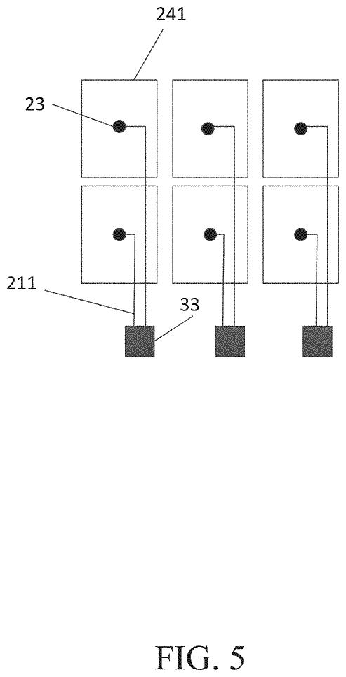

In order to further simplify the manufacturing process and reduce the production cost, as shown in FIG. 5, the metal mesh electrodes 241 correspond to the driving lines 211. For example, each of the metal mesh electrodes 241 corresponds to a driving line 211. In another embodiment, each of the metal mesh electrodes 241 corresponds to two driving lines 211.

The metal mesh electrode 241 is electrically connected with the corresponding driving line 211. In an embodiment of FIG. 5, one driving line 211 is arranged on the metal mesh electrode 241, where the metal mesh electrode 241 and the driving line 211 correspond to the positions of the gaps between the sub-pixels 102. In other words, the metal mesh electrode 241 and the driving line 211 are arranged at the gaps between the sub-pixels 102.

The metal mesh electrode 241 and the driving line 211 are disposed on different metal layers, and the metal mesh electrodes 241 are electrically connected with the driving lines 211 correspondingly through the connecting holes 23. The position of the connecting hole 23 corresponds to the position of a gap between the sub-pixels 102.

In an embodiment of FIG. 1, the metal mesh electrode 241 is disposed on the second metal layer 24, the driving line 211 is disposed on the first metal layer 21, and the second metal layer 24 is disposed above the first metal layer 21.

Each rectangular frame in FIG. 5 is defined as an outer contour of a metal mesh electrode 241, the display screen further includes a plurality of binding ends 33. One end of the driving line 211 is connected with the metal mesh electrode 241, the other end of the driving line 211 is connected with the binding end 33, and the binding end 33 is connected with the driving chip. In combination with FIG. 4, one end of the driving line 211 is connected with the intersection point of the first electrode 31 and the second electrode 32 in the mesh electrode 241.

Because the metal mesh electrodes and the driving lines are arranged at the gap between the sub-pixels, the aperture ratio of the display screen is increased and the power consumption is decreased. Moreover, since the touch control layer is directly arranged on the display layer, there is no need to attach the touch control layer to the display layer using an adhesive layer, thereby reducing the overall thickness of the display screen, simplifying the manufacturing process of the display screen, and reducing the production cost. In addition, because the driving lines are arranged inside the display screen, a frame size of the display screen is reduced.

The present disclosure further provides an electronic device and the electronic device includes any of above-mentioned display screens.

According to the display screen and the electronic device of the present disclosure, the metal mesh electrode and the driving lines are arranged in the gaps between the sub-pixels, thereby increasing the aperture ratio of the display screen and decreasing the power consumption. In addition, since the touch control layer is directly arranged and formed on the display layer, the overall thickness of the display screen is reduced.

As is understood by a person skilled in the art, the foregoing preferred embodiments of the present disclosure are illustrative rather than limiting of the present disclosure. It is intended that they cover various modifications and similar arrangements be included within the spirit and scope of the present disclosure, the scope of which should be accorded the broadest interpretation so as to encompass all such modifications and similar structures.

What is claimed is:

1. A display screen, comprising:
a display layer comprising a display region, wherein the display region comprises a plurality of sub-pixels arranged at intervals; and
a touch layer disposed above the display layer and comprising a plurality of metal mesh electrodes and a plurality of driving lines, wherein the metal mesh electrodes correspond to the driving line, the metal mesh electrodes are electrically connected with the corresponding driving lines, the metal mesh electrodes and the driving lines correspond to positions of gaps between the sub-pixels respectively, and the metal mesh electrode comprises a plurality of first electrodes arranged in a first direction and a plurality of second electrodes arranged in a second direction;
wherein the metal mesh electrodes and the driving lines are disposed on different metal layers, the metal mesh electrodes are electrically connected with the driving lines correspondingly through a plurality of connecting holes, and two adjacent metal mesh electrodes are arranged at intervals.

2. The display screen according to claim 1, wherein positions of the connecting holes correspond to the positions of the gaps between the sub-pixels.

3. The display screen according to claim 1, wherein the metal mesh electrodes are disposed on a second metal layer, the driving lines are disposed on a first metal layer, and the second metal layer is disposed on the first metal layer.

4. The display screen according to claim 1, wherein lengths of the metal mesh electrodes are equal, and widths of the metal mesh electrodes are equal.

5. The display screen according to claim 1, wherein positions of the metal mesh electrodes correspond to a position of the display region.

6. The display screen according to claim 1, wherein the first electrodes and the second electrodes are arranged in an intersection manner, and the driving lines are electrically connected with intersection points between the first electrodes and the second electrodes.

7. The display screen according to claim 1, wherein the display screen further comprises a plurality of binding ends, and one end of each of the driving lines is connected with a metal mesh electrode, and the other end of each of the driving lines is connected with a binding end.

8. A display screen, comprising:
a display layer comprising a display region, wherein the display region comprises a plurality of sub-pixels arranged at intervals; and
a touch layer disposed above the display layer and comprising a plurality of metal mesh electrodes and a plurality of driving lines, wherein the metal mesh electrodes correspond to the driving line, the metal mesh electrodes are electrically connected with the corresponding driving lines, the metal mesh electrodes and the driving lines correspond to positions of gaps between the sub-pixels respectively, and the metal mesh electrode comprises a plurality of first electrodes arranged in a first direction and a plurality of second electrodes arranged in a second direction.

9. The display screen according to claim 8, wherein the metal mesh electrodes and the driving lines are disposed on different metal layers, and the metal mesh electrodes are electrically connected with the driving lines correspondingly through a plurality of connecting holes.

10. The display screen according to claim 9, wherein positions of the connecting holes correspond to the positions of the gaps between the sub-pixels.

11. The display screen according to claim 9, wherein the metal mesh electrodes are disposed on a second metal layer, the driving lines are disposed on a first metal layer, and the second metal layer is disposed on the first metal layer.

12. The display screen according to claim 8, wherein two adjacent metal mesh electrodes are arranged at intervals.

13. The display screen according to claim 8, wherein lengths of the metal mesh electrodes are equal, and widths of the metal mesh electrodes are equal.

14. The display screen according to claim 8, wherein the positions of the metal mesh electrodes correspond to a position of the display region.

15. The display screen according to claim 8, wherein the first electrodes and the second electrodes are arranged in an intersection manner, and the driving lines are electrically connected with intersection points between the first electrodes and the second electrodes.

16. The display screen according to claim 8, wherein the display screen further comprises a plurality of binding ends, and one end of each of the driving lines is connected with a metal mesh electrode, and the other end of each of the driving lines is connected with a binding end.

17. An electronic device comprising a display layer, the display layer comprising:
a display region comprising a plurality of sub-pixels arranged at intervals; and
a touch layer disposed above the display layer and comprising a plurality of metal mesh electrodes and a plurality of driving lines, wherein the metal mesh electrodes correspond to the driving line, the metal mesh electrodes are electrically connected with the corresponding driving lines, the metal mesh electrodes and the driving lines correspond to positions of gaps between the sub-pixels respectively, and the metal mesh electrode comprises a plurality of first electrodes arranged in a first direction and a plurality of second electrodes arranged in a second direction.

18. The electronic device according to claim 17, wherein the metal mesh electrodes and the driving lines are disposed on different metal layers, and the metal mesh electrodes are electrically connected with the driving lines correspondingly through a plurality of connecting holes.

19. The electronic device according to claim 18, wherein positions of the connecting holes correspond to the positions of the gaps between the sub-pixels.

20. The electronic device according to claim 18, wherein the metal mesh electrodes are disposed on a second metal layer, the driving lines are disposed on a first metal layer, and the second metal layer is disposed on the first metal layer.
